(19) United States
(12) Patent Application Publication
(10) Pub. No.: US 2011/0024325 A1
(43) Pub. Date: Feb. 3, 2011

(54) WAFER BOX FOR THE TRANSPORT OF SOLAR CELL WAFERS

(76) Inventor: Matthias Winderlich, Hohenstein-Ernstthal (DE)

Correspondence Address: JORDAN AND HAMBURG LLP, 122 EAST 42ND STREET, SUITE 4000, NEW YORK, NY, 10168, US

(21) Appl. No.: 12/921,328

(22) PCT Filed: Mar. 4, 2009
(86) PCT No.: PCT/DE2009/000326

§ 371 Date: Sep. 27, 2010

(30) Foreign Application Priority Data
Mar. 6, 2008 (DE) 10 2008 012 928.3

(51) Int. Cl. H01L 21/673

(52) U.S. Cl. 206/710

(57) ABSTRACT

A wafer box for transporting solar cell wafers includes a bottom and guide elements for positioning the solar cell wafers. Four guide angles having centering ridges are provided coaxially with a centric axis on the upper side of the bottom, wherein the fronts of the centering ridges are oriented toward the inserted solar cell wafers. The distance between the fronts of two opposing centering ridges corresponds to the width of the solar cell wafers. A stacking wall having a grip opening is provided on each of two opposing sides of the bottom, and a support bottom is provided, so as to be guided at least on the centering ridges. The bottom has an opening on the centric axis, and has four apertures, for lifting rams for raising the solar cell wafers on the supporting bottom, on a concentric pitch circle at points of intersection with the diagonals of the bottom.

### BACKGROUND OF THE INVENTION

The invention relates to a transport container for transporting solar cell wafers, hereinafter referred to in an abbreviated manner as a “wafer box,” comprising a bottom and guide elements for positioning the solar cell wafers inside the wafer box.

A variety of transport containers are known from the prior art, in which planar workpieces can be transported. Especially, in the case of solar cell wafers, it is important to safely transport a technically predetermined quantity of thin and sensitive solar cell wafers, and gently place them into, or remove them from, the wafer box.

DE 20 2006 005 284 U1 describes a dimensionally stable solar cell container comprising a rectangular or square container bottom, which has integrally formed lateral walls on all sides. At least two lateral walls have slot-shaped apertures. The solar cell container is produced so as to directly receive the largest solar cells to be produced. Adapted inserts are available for smaller solar cells and can be inserted in the solar cell container and engaged in recesses in the upper edge of the solar cell container by way of lugs. Each specific size of solar cell requires a separate insert. The inserts have slot-shaped apertures matching the solar cell containers.

Receiving openings for lifting bodies are provided in the bottom of the solar cell container. The lifting bodies penetrate the receiving openings in order to remove the solar cells, and act directly against the lowest solar cell so as to allow the solar cell to be lifted and removed from the solar cell container and/or the insert.

It is the object of the invention to provide a technically simple wafer box for transporting solar cell wafers, which has a relatively low weight and by which the solar cell wafers can be safely transported and gently added and removed. The wafer box should be stackable and enable the attachment of separate elements of modern logistics.

### SUMMARY OF THE INVENTION

The invention achieves the object by. Advantageous refinements of the invention will be described hereinafter in more detail in conjunction with the description of the preferred embodiment of the invention, including the drawing.

The wafer box according to the invention comprises a bottom having guide elements on the upper side thereof for positioning the solar cell wafer inside the wafer box. Furthermore, a support bottom is provided, onto which the solar cell wafers can be placed. Four guide angles, comprising an angle having two centering ridges, are provided coaxially with a centric axis as guide elements, wherein the fronts of the centering ridges are oriented toward the inserted solar cell wafers.

The distance between the fronts of the centering ridges, which are positioned in parallel, opposite each other, corresponds to the width of the inserted solar cell wafers. An opening is provided in the bottom, on the centric axis, and is designed to be as large as possible so as to prevent air from being trapped when inserting and removing the solar cell wafers, which would make the handling of the solar cell wafers more difficult. This opening can also be configured in multiple parts in the form of a plurality of small openings.

Four apertures are provided on a pitch circle concentric with the centric axis and at the points of intersection with the diagonals on the bottom. Well known lifting elements can extend through these apertures for removing the solar cell wafers. A stacking wall having a grip opening is provided on each of two opposing sides of the bottom.

The support bottom corresponds to a level plate, which has a corresponding centric opening, in the same manner as centric opening in the bottom of the wafer box. The outer contour of the support bottom substantially corresponds to that of the solar cell wafers. A guide land, which engages in the region of two abutting centering ridges, is configured on the support bottom, at least in this region between two parallel centering ridges. Advantageously, such guide lands are provided in the corresponding regions between all parallel centering ridges.

Corresponding centering lands can also engage in the grip openings in the stacking walls. The support bottom configured according to the invention is thereby supported inside the wafer box in a torsion-proof manner and cannot fall out of the wafer box unimpaired.

The parallel distances between centering ridges depend on the technically stipulated dimensions of the solar cell wafers. At present, square or pseudo-square solar cell wafers measuring 125×125 mm, 156×156 mm and 210×210 mm in width are used. On this basis, it is advantageous to uniformly equip the wafer box according to the invention with a bottom measuring approximately 240×240 mm, on which the guide angles are disposed at appropriately varying distances, which is to say, a special wafer box having specially disposed guide angles and a related support bottom is provided for each type of solar cell wafer. In practice, it has proven useful, in the case of extraordinarily high quantities, to form the guide angles integrally, directly on the bottom. However, it is also possible to detachably dispose the guide angles in a variable manner in corresponding seats.

The guide angles for the present largest solar cell wafers measuring 210×210 mm are configured as angled support columns in the region of the outer edges of the bottom.

The diameter of the pitch circle, on which the four apertures for the lifting elements are located, is always smaller than a circle connecting the fronts of the centering ridges for the smallest solar cell wafer to be transported in the wafer box (using the same bottom), that is, having the dimensions 125×125 mm. In this way, independently of the actual type of solar cell wafers, the same lifting elements may always be used. The lifting forces that occur are similarly gently transmitted to the stack of solar cell wafers by way of the support plate.

The entire wafer box (without the support bottom) is usually produced in one piece from impact-resistant and dimensionally stable plastic. Such wafer boxes are also easy to clean, because during use they collect a lot of dirt, notably due to the abrasion of solar cell wafers.

The invention will be described in more detail hereinafter based on two exemplary embodiments.

### BRIEF DESCRIPTION OF THE DRAWINGS

FIG. 1 is a perspective top view of a wafer box according to a first embodiment of the invention for a wafer size of 125×125 mm;

FIG. 2 is a perspective a view of the underside of the bottom of the wafer box of FIG. 1; and

FIG. 3 is a perspective top view of a wafer box according to a second embodiment of the invention for the current maximum wafer size of 210×210 mm.

The dimensions have been adapted to currently common solar cell wafers. In the future, different dimensions may become applicable.

### DETAILED DESCRIPTION OF THE INVENTION

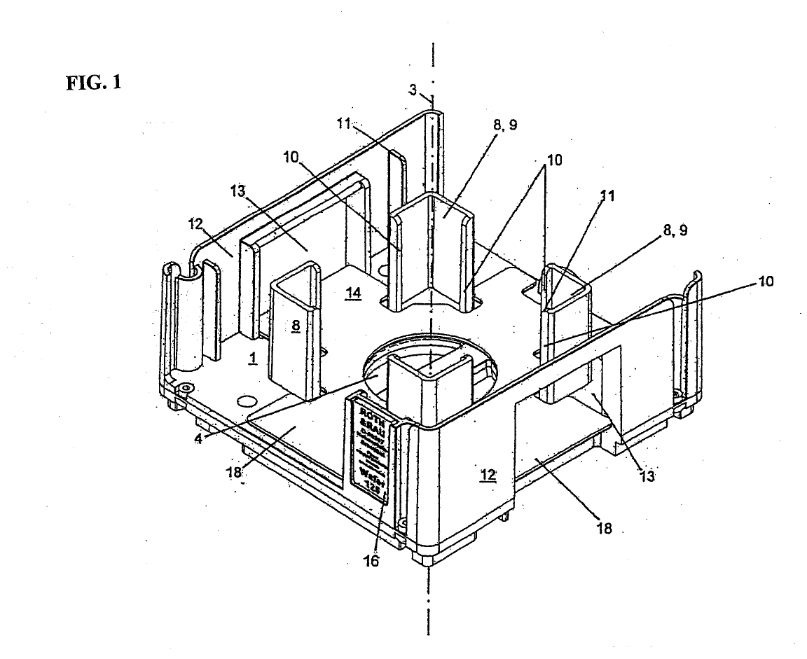

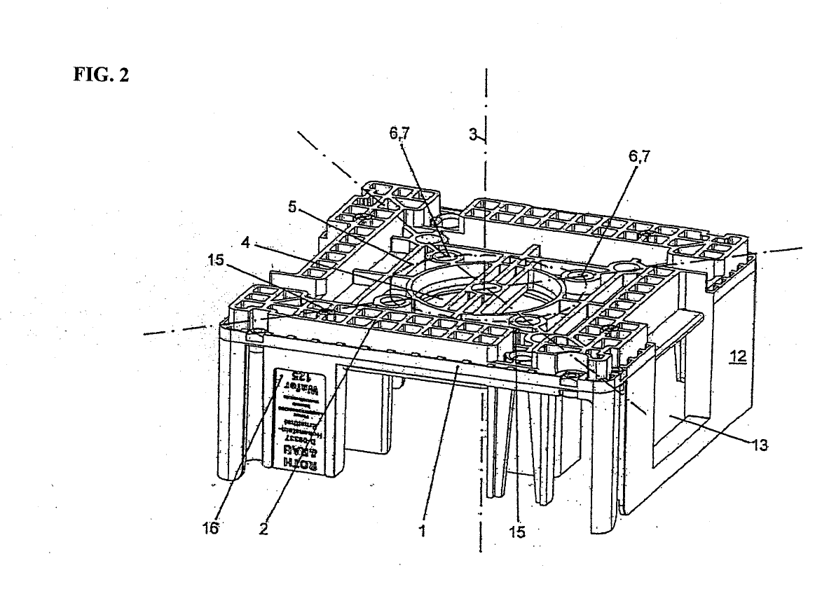

Referring to FIGS. 1 and 2, a wafer box according to a first embodiment of the invention is shown therein, and comprises a bottom 1, which, on the underside thereof, has a plurality of ribs 2 in the known manner, so as to assure high dimensional stability. Given the currently customary wafer sizes of 125×125 mm, 156×156 mm, or 210×210 mm, the bottom 1 has standard outer dimensions of approximately 240×240 mm.

As is apparent, in particular, from FIG. 2, an opening 4 is provided in the bottom 1 concentrically with a centric axis 3, and four apertures 6 are provided on a pitch circle 5 at the intersecting points with the diagonals 7 of the bottom 1.

As shown in FIG. 1, four guide angles 8 are disposed on the upper side of the bottom 1, likewise on the diagonals 7. Each guide angle 8 comprises an angle 9 and a centering ridge 10 at the end thereof, with the front of the ridge being directed toward the inserted solar cell wafers. Insertion chamfers 11 are configured at the upper edges of the centering ridges 10.

The radial position of the guide angles 8 with respect to the axis 3 is dependent on the size of the solar cell wafers inserted in each specific case. FIG. 1 shows, by way of example, an embodiment for solar cell wafers measuring 125×125 mm. A wafer box intended for 156×156 mm would be configured equivalently, only with a slightly larger distance for the guide angles 8.

Two stacking walls 12 are provided on two opposing sides of the bottom 1, each having a grip opening 13 extending to the bottom. The stacking walls 12 ensure secure stacking of multiple wafer boxes on top of each other and good handling.

A key element of the invention is that the wafer box has a support bottom 14. The support bottom 14 serves as a stable planar support for the solar cell wafers and at the same time reduces the surface pressure of lifting rams, which may project through the apertures 6 in the bottom 1 for lifting the solar cell wafers located on the support bottom 14. The lifting forces are absorbed by the support bottom 14 and, in practice, act uniformly and gently on the solar cell wafers, over substantially the entire surface of the support bottom 14.

The support bottom 14 is a stable planar plate having an outer configuration that ensures good guidance within the centering ridges 10 of the guide angles 8. The outer contour of the support bottom 14 is enlarged between each two guide angles 8 in a manner constituting guide lands 18. The guide lands 18 ensure additional anti-torsion guidance of the support bottom 14, and consequently, of a stack of solar cell wafers placed thereon.

In the first exemplary embodiment, the support bottom 14 comprises further guide lands 18, which engage in the grip openings 13 of the stacking walls 12. This provides additional guidance, and the support bottom 14 cannot fall out of the wafer box unimpaired, in the unused state.

In a known manner, three pins 15 are provided on the underside in the bottom 1 for machine-readably encoding the type of the solar cell wafer and controlling the running direction of the wafer box in a mechanical transport device.

Furthermore, a seat 16 is provided on one side on the bottom 1, into which, for example, a visually readable type label, with or without scannable information, is introduced.

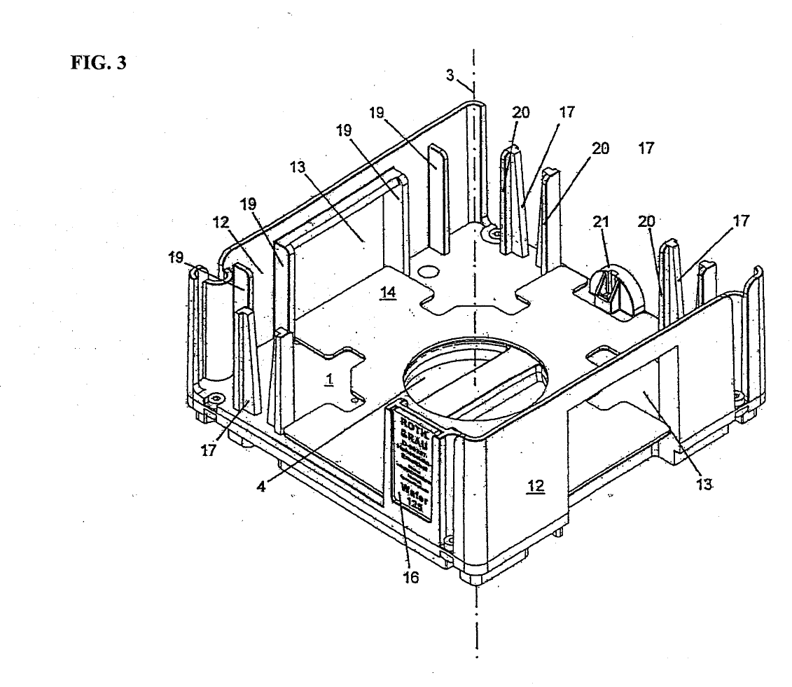

FIG. 3 depicts a wafer box according to a second exemplary embodiment, which is suited for the current largest solar cell wafers having dimensions of 210×210 mm. The bottom 1 is identical to the bottom according to the first exemplary embodiment. Four centering ridges 19, of which the two inner centering ridges 19 also define the grip opening 13, are configured as guide angles on the insides of the two stacking walls 12.

Centering ridges 20 are configured on support columns 17 on both sides between the stacking walls 12. In FIG. 3, two support columns 17 are connected to each other at the front, so as to form a seat 16. By way of example, an RFID pocket 21 for attaching RFID (radio frequency identification) for automatic logistics systems is provided on the bottom 1 on the opposite side of the wafer box.

In practice, the wafer boxes according to the first and second exemplary embodiments form related units, i.e., the four centering ridges 19 on the stacking walls 12 are also present in the wafer boxes for solar cells having the dimensions of 125×125 mm and 156×156 mm, such that they further stabilize the stacking walls 12.

1-4. (canceled)

5. A wafer box for transporting solar cell wafers, comprising:
a bottom including an opening coaxial with a centric axis, said bottom further including four apertures located on a pitch circle concentric with said centric axis at points of intersection with diagonals of the bottom;
four guide angles comprising an angular structure having two centering ridges, said guide angles being arranged coaxially with the centric axis on an upper side of the bottom, fronts of the centering ridges being oriented toward the solar cell wafers when inserted, a distance between the fronts of two opposing ones of the centering ridges generally corresponding to the width of the solar cell wafer;
a stacking wall including a grip opening being disposed on each of two opposing sides of the bottom; and
a support bottom including an outside configuration configured so that the support bottom is guided at least on the centering ridges.

6. The wafer box according to claim 5, wherein two of said four guide angles are configured as angled support columns at least in a region of an outside edge of the bottom.

7. The wafer box according to claim 5, wherein the pitch circle is located inside a circle connecting the fronts of the centering ridges.

8. The wafer box according to claim 6, wherein the pitch circle is located inside a circle connecting the fronts of the centering ridges.

9. A wafer box according to claim 5, further comprising a seat being disposed on one side of the bottom, into which a type label or elements for logistics elements can be introduced.

10. A wafer box according to claim 6, further comprising a seat being disposed on one side of the bottom, into which a type label or elements for logistics elements can be introduced.

11. A wafer box according to claim 7, further comprising a seat being disposed on one side of the bottom, into which a type label or elements for logistics elements can be introduced.

12. A wafer box according to claim 8, further comprising a seat being disposed on one side of the bottom, into which a type label or elements for logistics elements can be introduced.
